(19) United States
(12) Patent Application Publication
(10) Pub. No.: US 2014/0191653 A1
(43) Pub. Date: Jul. 10, 2014

(54) PROTECTIVE DIFFUSIVE COATING FOR LED LAMP

(71) Applicant: Cree, Inc., Durham, NC (US)

(72) Inventors: Mark Edmond, Raleigh, NC (US); Shaow B. Lin, Morrisville, NC (US); Gerald H. Negley, Chapel Hill, NC (US); Paul Kenneth Pickard, Morrisville, NC (US)

(73) Assignee: Cree, Inc., Durham, NC (US)

(21) Appl. No.: 13/951,206

(22) Filed: Jul. 25, 2013

Related U.S. Application Data
(63) Continuation-in-part of application No. 13/738,575, filed on Jan. 10, 2013.

(51) Int. Cl. H05B 33/22; H01L 33/52

(52) U.S. Cl. CPC H05B 33/22; H01L 33/52
USPC 313/512; 313/116; 438/27

(57) ABSTRACT

The present disclosure discloses LED lamps and enclosures comprising light transparent polymer coatings comprising light diffusing particles as well as methods for providing improved luminous intensity distribution. More particularly, the present disclosure relates to enclosures comprising light-transparent polymer coatings comprising a light diffusing particles on at least one surfaces of the enclosure of an LED lamp.

### CROSS-REFERENCE TO RELATED APPLICATIONS

This application is a continuation-in-part of U.S. application Ser. No. 13/738,575, filed Jan. 10, 2013, the entire contents of which is hereby incorporated by reference in its entirety.

### TECHNICAL FIELD

The present disclosure relates to light emitting diode (LED) lamps and methods of applying coatings onto the surface of an enclosure of an LED lamp to improve luminous intensity distribution. More particularly, the present disclosure relates to enclosures comprising optically clear transparent coatings comprising light-diffusing particles and LED lamps made thereby.

### BACKGROUND

Light emitting diode (LED) lighting systems are becoming more prevalent as replacements for older lighting systems. LED systems are an example of solid state lighting (SSL) and have advantages over traditional lighting solutions such as incandescent and fluorescent lighting because they use less energy, are more durable, operate longer, can be combined in multi-color arrays that can be controlled to deliver virtually any color light, and generally contain no lead or mercury.

Angular uniformity, also referred to as luminous intensity distribution, is important for LED lamps that are to replace standard incandescent bulbs and other lighting devices. The geometric relationship between the filament of a standard incandescent bulb and the glass envelope, in combination with the fact that no electronics or heat sink is needed, allow light from an incandescent bulb to shine in a relatively omnidirectional pattern. That is, the luminous intensity of the incandescent bulb is distributed relatively evenly across angles in the vertical plane for a vertically oriented bulb from the top of the bulb to the screw base, with only the base itself presenting a significant light obstruction. LED bulbs typically include electronic circuitry and a heat sink, which may obstruct the light in some directions.

Color parameters are typically part of commercial, state or federal standards because pleasing color is important to consumer acceptance of alternative lighting products. Luminous intensity distribution is also typically part of such standards. For example, in the United States, the Bright Tomorrow Lighting Competition (L Prize™) has been authorized by the Energy Independence and Security Act of 2007 (EISA). The L Prize is described in Bright Tomorrow Lighting Competition (L Prize™), Jun. 26, 2009, Document No. 08NT006643, the disclosure of which is hereby incorporated herein by reference. The L Prize winner's product must conform to a number of requirements, including, but not limited to those related to color and luminous intensity distribution.

### SUMMARY

In a first embodiment, an LED lamp is provided, the LED lamp comprising an enclosure about one or more LEDs, the enclosure comprising an interior diffuse surface and an exterior diffuse surface separated from the interior surface.

In a second embodiment, an LED lamp is provided comprising an enclosure about one or more LEDs, the enclosure comprising an interior surface separated from an exterior surface by a thickness, the enclosure comprising deposited on the exterior surface a light-transparent coating comprising light-diffusing particles.

In a third embodiment, LED lamp is provided, the LED lamp comprising an enclosure about one or more LEDs. The enclosure comprises a diffuse interior surface capable of diffracting light emitted from the one or more LEDs and an exterior surface separated from the diffuse interior surface by a thickness. A light-transparent coating is deposited on the exterior surface, the light-transparent coating comprising light-diffusing particles.

In a fourth embodiment, an LED lamp is provided comprising an enclosure about one or more LEDs. The enclosure comprises an interior surface and an exterior surface separated from the interior surface by a thickness, the thickness comprising one or more lanthanide compounds and/or lanthanide elements. A light-transparent coating is deposited on the exterior surface, the light-transparent coating comprising light-diffusing particles.

In a fifth embodiment, a method of providing improved luminous intensity distribution of a light emitting diode (LED) lamp is provided. The method comprises diffusing light emitted by one or more LEDs capable of emitting light of one or more wavelengths by passing the one or more wavelengths of light through a coating deposited on an exterior surface of an enclosure at least partially surrounding the one or more LEDs, the coating comprising a transparent polymer matrix and an amount of light-diffusing particles; and providing a normalized luminous intensity of between 0.75 to 1.15 maintained over a range of 0 to 135 degrees of angle of measurement.

In a sixth embodiment, a method of providing improved luminous intensity distribution of a light emitting diode (LED) lamp, the method comprising coating an enclosure surrounding the one or more LEDs, the enclosure having an interior surface separated from an exterior surface by a thickness, the coating comprising light-diffusing particles in an amount sufficient to diffuse light emitted by the one or more LEDs; and providing a normalized luminous intensity of 0.75 to 1.25 maintained over the range of 0 to 135 degrees of angle of measurement. In other aspects, a normalized luminous intensity of 0.75 to 1.25 maintained over the range of 0 to 135 degrees of angle of measurement. In other aspects, a normalized luminous intensity of 0.8 to 1.2 is maintained over the range of 0 to 135 degrees of angle of measurement.

In a seventh embodiment, an enclosure for a light emitting diode (LED) lamp is provided, the enclosure comprising an interior surface and an exterior surface separated by a thickness from the interior surface and a coating deposited on at least a portion of the enclosure, the coating comprising a light-transparent polymer matrix and an amount of light-diffusing particles distributed or dispersed therein.

### BRIEF DESCRIPTION OF THE DRAWINGS

FIG. 1A is a plan view of an embodiment of a LED lamp usable in embodiments of the present disclosure.

FIG. 1B is a partial exploded view of a section of the LED lamp enclosure of FIG. 1A representing various embodiments of the present disclosure.

FIG. 1C is a sectional view of an exemplary LED lamp enclosure of FIG. 1A.

FIG. 1D is a sectional view of an exemplary LED lamp enclosure of FIG. 1A.

FIG. 2A is a perspective view of anLED lamp.

FIG. 2B is a partial exploded perspective view of the LED lamp of FIG. 2A.

FIG. 3 is an exploded perspective view of the lamp of FIG. 2A.

FIG. 4A is a front view of an embodiment of a LED lamp suitable for coating in accordance with the present disclosure.

FIG. 4B is a side view of the lamp of FIG. 4A.

FIG. 5A is a section view taken along line A-A of FIG. 4A.

FIG. 5B is a section view taken along line B-B of FIG. 4B.

FIG. 6A is a perspective view of a BR-like LED lamp usable in embodiments of the present disclosure.

FIG. 6B is a perspective view of a PAR-like LED lamp usable in embodiments of the present disclosure.

FIG. 7 is a sectional view of a LED lamp in accordance with embodiments of the present disclosure.

FIG. 8A, FIG. 8B, and FIG. 8C are perspective views of an enclosure with coatings according to some example embodiments of the present disclosure.

FIGS. 9A, 9B, and 9C represent luminous intensity distribution profiles corresponding to control and exemplary example embodiments, respectively, of the present disclosure.

### DETAILED DESCRIPTION

The present disclosure provides, among other aspects, for an LED lamp with an enclosure comprising one or more coatings on one or both of the interior and exterior surfaces of the enclosure. The coating is configured, among other things, to improve luminous intensity distribution, but may also prevent egress in or out of the enclosure upon a breach. Thus, in one aspect the coating, which may include or be part of a plurality of discrete layers of the same or different materials, improves luminous intensity distribution of an LED lamp.

In one embodiment, an LED lamp is provided that comprises an enclosure about one or more LEDs, the enclosure having a diffuse interior surface capable of diffracting light emitted from the one or more LEDs. An exterior surface of the enclosure is separated from the diffuse interior surface by a thickness. A light-transparent coating is deposited on the exterior surface, the light-transparent coating comprising light-diffusing particles. The aforementioned LED lamp provides improved luminous intensity distribution.

In another embodiment, an LED lamp is provided that comprises an enclosure about one or more LEDs, the enclosure having a diffuse interior surface capable of diffracting light emitted from the one or more LEDs. The enclosure comprises one or more light-filtering agents, e.g., lanthanide elements or lanthanide compounds or other suitable materials coated on, or otherwise doped into, the enclosure. An exterior surface of the enclosure is separated from the diffuse interior surface by a thickness. A light-transparent coating is deposited on the exterior surface, the light-transparent coating comprising light-diffusing particles. The aforementioned LED lamp provides improved luminous intensity distribution.

The present disclosure also provides, among other aspects, an LED lamp comprising an enclosure about one or more LEDs, the enclosure comprising an interior diffuse surface and an exterior diffuse surface separated from the interior surface.

In another embodiment, the present disclosure provides an LED lamp comprising an enclosure having an interior surface and an exterior surface. The enclosure may be coupled to a threaded metal base and enclosing at least one LED element. The coating herein disclosed at least partially covers the exterior surface of the enclosure. The coating may include a plurality of discrete layers of the same or different material, or may be deposited on one or more existing layers previously deposited on the enclosure or the coating can be at least partially covered by one or more layers (“cover layers”).

In yet another embodiment, the present disclosure provides an enclosure for a light emitting diode (LED) lamp, the enclosure comprising an interior surface and an exterior surface separated by a thickness from the interior surface. A coating is deposited on at least a portion of the enclosure, the coating comprising a light-transparent polymer matrix and an amount of light-diffusing particles distributed or dispersed therein. The thickness of the enclosure can comprises one or more lanthanide elements or lanthanide compounds incorporated therein or deposited on the interior surface. The interior surface of the enclosure can be diffuse, e.g., etched, frosted, or sandblasted.

In another aspect the one or more deposited layers can contain one or more, phosphors, lanthanide elements and compounds and/or other optical materials. The coating herein disclosed is configured to control and/or modulate luminous intensity distribution throughout the angle of incidence with respect to the enclosure.

The present disclosure also provides, among other aspects, the preparation and process of applying the presently disclosed coating. Thus, precursor components and/or a curable coating for an LED lamp are provided. Accordingly, in one embodiment of the present disclosure is provided a precursor component and/or a curable coating for an LED lamp. In some aspects, one or more of the precursor components and/or curable coating has at least one reactive group suitable for physical or chemical coupling and/or crosslinking. In additional embodiments, an essentially solvent free coating composition is provided with long-term self-life suitable for the manufacturing of large numbers of LED lamps with excellent process latitude. This disclosure provides a solvent-free silicone elastomer compound that can be successfully applied as coating for glass light bulb. No solvent is required to provide LED light lamps with improved luminous intensity distribution and/or shatter-proof protection.

This disclosure further provides means to stabilize the viscosity of solvent-free silicone elastomer mixtures from increasing and extend the working life (pot life) to days. The quality and property of the solvent-free silicone elastomer mixtures are not compromised e.g., have a rapid increase in viscosity over time, using the current methods and compositions. This makes it extremely desirable and efficient to carry out large scale production coating processing of LED lamps.

Embodiments of the present disclosure now will be described more fully hereinafter with reference to the accompanying drawings, in which embodiments of the present disclosure are shown. This present disclosure may, however, be embodied in many different forms and should not be construed as limited to the embodiments set forth herein. Rather, these embodiments are provided so that this disclosure will be thorough and complete, and will fully convey the scope of the claims to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated' listed items.

It will be understood that when an element such as a coating or a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer or region to another element, layer or region as illustrated in the figures. It will be understood that these terms are intended to encompass different orientations of the device in addition to the orientation depicted in the figures.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof. Unless otherwise defined, all terms (including technical and scientific terms) used herein have the same meaning as commonly understood by one of ordinary skill in the art to which this present disclosure belongs. It will be further understood that terms used herein should be interpreted as having a meaning that is consistent with their meaning in the context of this specification and the relevant art and will not be interpreted in an idealized or overly formal sense unless expressly so defined herein.

Unless otherwise expressly stated, comparative, quantitative terms such as “less” and “greater”, are intended to encompass the concept of equality. As an example, “less” can mean not only “less” in the strictest mathematical sense, but also, “less than or equal to.”

The terms “LED” and “LED device” as used herein may refer to any solid-state light emitter. The terms “solid state light emitter” or “solid state emitter” may include a light emitting diode, laser diode, organic light emitting diode, and/or other semiconductor device which includes one or more semiconductor layers, which may include silicon, silicon carbide, gallium nitride and/or other semiconductor materials, a substrate which may include sapphire, silicon, silicon carbide and/or other microelectronic substrates, and one or more contact layers which may include metal and/or other conductive materials. A solid-state lighting device produces light (ultraviolet, visible, or infrared) by exciting electrons across the band gap between a conduction band and a valence band of a semiconductor active (light-emitting) layer, with the electron transition generating light at a wavelength that depends on the band gap. Thus, the color (wavelength) of the light emitted by a solid-state emitter depends on the materials of the active layers thereof. In various embodiments, solid-state light emitters may have peak wavelengths in the visible range and/or be used in combination with lumiphoric materials having peak wavelengths in the visible range. Multiple solid state light emitters and/or multiple lumiphoric materials (i.e., in combination with at least one solid state light emitter) may be used in a single device, such as to produce light perceived as white or near white in character. In certain embodiments, the aggregated output of multiple solid-state light emitters and/or lumiphoric materials may generate warm white light output having a color temperature range of from about 2200K to about 6000K.

The terms “crosslink” and “crosslinking” as used herein refer without limitation to joining (e.g., adjacent chains of a polymer) by creating covalent or ionic bonds. Crosslinking can be accomplished by known techniques, for example, thermal reaction, chemical reaction or ionizing radiation (for example, UV/Vis radiation, electron beam radiation, X-ray, or gamma radiation, catalysis, etc.).

The phrase “light diffusing particles” is used herein to be inclusive of particles of an index of refraction differing from that of the matrix material they are contained, dispersed, or distributed in. For example, in a matrix, e.g., polymer matrix, of a first index of refraction, light-diffusing particles of a second index of refraction differing by +/− about 0.3 to about 0.001, by about 0.3 to about 0.01, or about 0.3 to about 0.05, can be used. Other index of refraction deltas can be used within these ranges, for example, any possible integral of 0.001 between the upper and lower limits stated. Other combination of matrix material and particles of particular index of refraction can be used provided that the coating functions to diffuse light emitted by the LEDs. In certain aspects, the light diffusing particles, depending on their chemical composition and/or particle size and/or index of refraction, coupled with the incident angle of light emitted by the LED, are capable of providing scattering, diffusing, refracting and/or reflecting of one or more wavelengths of the light emitted by the LED. As used herein, the term “refracting” is inclusive of scattering, reflecting, and/or diffusing of impinging light.

The phrase “precursor component” is used herein interchangeably with “coating matrix” and “matrix,” and refers without limitation to one or more materials or one or more compositions of matter that are capable of transitioning from a liquid to a solid or gel suitable for use in or with a light emitting device as a coating of, around, or about one or more components of the lighting device.

A solid-state lighting system may take the form of a lighting unit, light fixture, light bulb, or a “lamp.” A solid-state lighting system includes an LED lighting system. An LED lighting system may include, for example, a packaged light emitting device including one or more light emitting diodes (LEDs), which may include inorganic LEDs, which may include semiconductor layers forming p-n junctions and/or organic LEDs (OLEDs), which may include organic light emission layers. Light perceived as white or near-white may be generated by a combination of red, green, and blue (“RGB”) LEDs. Output color of such a device may be altered by separately adjusting supply of current to the red, green, and blue LEDs. Another method for generating white or near-white light is by using a lumiphor such as a phosphor. Still another approach for producing white light is to stimulate phosphors or dyes of multiple colors with an LED source. Many other approaches can be taken.

An LED lamp may be made with a form factor that allows it to replace a standard incandescent bulb, or any of various types of fluorescent lamps. LED lamps often include some type of optical element or elements to allow for localized mixing of colors, collimate light, or provide a particular light pattern. Sometimes the optical element also serves as an envelope or enclosure for the electronics and or the LEDs in the lamp.

Since, ideally, an LED lamp designed as a replacement for a traditional incandescent or fluorescent light source needs to be self-contained; a power supply is included in the lamp structure along with the LEDs or LED packages and the optical components. A heatsink is also often needed to cool the LEDs and/or power supply in order to maintain appropriate operating temperature. The power supply and especially the heatsink can often hinder some of the light coming from the LEDs or limit LED placement. Depending on the type of traditional bulb for which the solid-state lamp is intended as a replacement, this limitation can cause the solid-state lamp to emit light in a pattern that is substantially different than the light pattern produced by the traditional light bulb that it is intended to replace.

An LED lamp may be constructed with an enclosure or “bulb”-like structure, which may be frangible or non-frangible. The LED lamp may contain an environment within the enclosure different from that of the ambient environment it is used, for example, the enclosure may contain an optically transmissive media, such as a liquid, gel, or gas. Breach of the frangible enclosure may result in egress in or out of the enclosure of the optically transmissive media (e.g., gas) or a substance (e.g., phosphor, diffuser, etc.,) that can compromise one or more features or properties of the LED lamp, such as its lifetime, its color rendering index (CRI), its luminous output or intensity, and its heat dissipation capability. The LED lamp may be accidentally contacted with a force that may only crack the enclosure or it may completely fragment the enclosure. Containment of the environment of the enclosure and/or containment of at least a portion of the fragmented and/or breached enclosure using the coating herein disclosed is a desirable improvement for an Edison incandescent light replacement device. In certain aspects, the LED lamp coated as described herein is not under vacuum or partial pressure relative to its ambient environment, in contrast to an Edison bulb.

Likewise, the ability of the LED lamp to maintain some level of performance after breach of its enclosure is a desirable attribute that cannot be achieved with an Edison bulb due to the rapid burn out of the tungsten filament, for example. This provides the LED lamp with the capability for emergency lighting applications. For example the presently disclosed LED lamp can be used where it is likely its enclosure would be compromised, yet the luminosity of the LED lamp would nonetheless continue for a desirable time thereafter. For example, the environment within the frangible enclosure can be air or other gas mixture and the ambient environment can be liquid, the coating preventing the egress of the liquid and/or the gas for a time after breach of the enclosure to provide emergency lighting. The coating may be configured to allow minutes, hours, days, or weeks of acceptable and/or functional operation under a condition where the frangible enclosure is partially or completely compromised. The coating can be selected based on its diffusion and/or transport properties of certain gases and liquids and/or to complement its optical transmissive properties.

For example, an LED lamp may include an environment comprising one or more gases within the optically transmissive, frangible enclosure so as to provide thermal coupling to the LED array and any power supply components that might be included therein. A combination of gasses can be used. Examples include one or more of inert gases (e.g., helium, neon, argon, krypton, etc.), hydrogen, halocarbons such as chlorofluorocarbons, and hydrochlorofluorocarbon. In one aspect, gas or gases with a thermal conductivity in milliwatts per meter Kelvin (mW/m-K) of from about 45 to about 180 can be used. For purposes of this disclosure, thermal conductivities are given at standard temperature and pressure (STP). It is to be understood that thermal conductivity values of gasses may change at different pressures and temperatures. Gasses can be used with an embodiment of the invention where the gas has a thermal conductivity of at least about 45 mW/m-K, least about 60 mW/m-K, at least about 70 mW/m-K, least about 100 mW/m-K, at least about 150 mW/m-K, from about 60 to about 180 mW/m-K, or from about 70 to about 150 mW/m-K. The coating may be configured to allow minutes, hours, days, or weeks of acceptable and/or functional operation without overheating under a condition where the frangible enclosure is partially or completely compromised, the gas or gases escape or change in composition. The coating can be selected based on its diffusion and/or transport properties of the particular gases used and/or to complement its optical transmissive properties.

Of course, the coating disclosed herein can provide for some level of resistance to breach of the frangible enclosure by virtue of its physical properties and/or coating thickness, such as its elongation and compressibility properties. These attributes, alone or in combination are provided to the LED lamp with the coating herein described.

In other embodiments, the coating described herein can be applied to at least a portion of one or both of the external or interior surfaces of the enclosure to contain at least a portion of particulates or particulate material present within the LED lamp or formed upon breach thereof. In one aspect a tacky coating internally applied to a frangible enclosure can be used to retain such particulate matter upon breach of the enclosure. In one aspect the particulate material is phosphor or lumiphoric material, diffuser, or lanthanide oxide. The coating can be applied over at least a portion of one or more preexisting layers and/or under one or more additional layers containing the particulate materials or other optical materials. The coating can completely cover the one or more preexisting or additional layers.

Solid state light emitters may be used individually or in combination with one or more lumiphoric materials (e.g., phosphors, scintillators, lumiphoric inks) and/or optical elements to generate light at a peak wavelength, or of at least one desired perceived color (including combinations of colors that may be perceived as white). Inclusion of lumiphoric (also called ‘luminescent’) materials in lighting devices as described herein may be accomplished by direct coating on solid state light emitter, adding such materials to coatings, adding such materials to lenses, by embedding or dispersing such materials within lumiphor support elements, and/or coating such materials on lumiphor support elements. Other materials, such as light scattering elements (e.g., particles) and/or index matching materials, may be associated with a lumiphor, a lumiphor binding medium, or a lumiphor support element that may be spatially segregated from a solid state emitter.

Embodiments of the present disclosure provide a solid-state lamp with centralized light emitters, more specifically, LEDs (hereinafter, interchangeably used with “LED lamp” or “LED bulb” Multiple LEDs can be used together, forming an LED array. The LEDs can be mounted on or fixed within the lamp in various ways. It should also be noted that the term “lamp” is meant to encompass not only a solid-state replacement for a traditional incandescent bulb as illustrated herein, but also replacements for fluorescent bulbs, replacements for complete fixtures, and any type of light fixture that may be custom designed as a solid state fixture for mounting on walls, in or on ceilings, on posts, and/or on vehicles, as well as downlights, streetlights, highway lights etc., depending on the desired light distribution and output characteristics.

The enclosure of the LED lamp of the present disclosure can be made of glass, ceramic, or plastic. In one aspect the enclosure is fragile e.g., made of glass. The thickness of the enclosure as measured between the interior surface and the exterior surface can be between 0.4 mm to about 1.7 mm. The interior surface of the enclosure can be diffuse, or can be smooth or not roughened or etched. As used herein, diffuse refers to a surface roughness that is at least capable of diffusing, diffracting, reflecting, and/or scattering incident light. Conventional methods of providing diffuse surfaces for glass can be used, such as etching, frosting, or sandblasting. Other techniques can be used to provide a diffuse enclosure surface. The enclosure can be doped with one or more light filtering agents, coated (interior or exterior) with one or more layers comprising one or more light filtering agents, phosphors, light diffusing particles, etc., or contain optically transmissive media having one or more light filtering agents, phosphors, light diffusing particles, etc. each and/or all of which provide optical properties that independently or synergistically contribute to the performance and properties of the LED lamp.

### Coating Materials-Light-Transparent Polymer Matrix and Light-Diffusing Particles

In one embodiment, a light transmissive coating is used. The light transmissive coating can be a curable coating. The curable coating and/or precursor components herein disclosed provide, among other things, a resultant light transparent and optionally, a low index of refraction polymeric matrix. Regardless of the visual appearance of the coating (e.g., opaque or cloudy depending on the loading of light-diffusing particles) the coating can nonetheless be “light-transparent.” Suitable curable coating and/or one or more precursor components providing low index of refraction or highly visible light transparent organic polymers include silicones, polyesters, polyurethanes, acrylics (e.g., polyacrylates, polymethacrylates, hereafter “poly(meth)acrylates”), epoxies, fluoropolymers, and combinations thereof.

Preferably, the resultant light transparent polymeric matrix has an index of refraction of less than about 1.6, preferably less than about 1.5 or between about 1.5 to about 1.3. In one aspect, the light transparent polymeric matrix is transparent in the visible spectra and/or at least a portion of the UV region (e.g., from about 200 nanometers to about 850 nanometers). In other aspects, the light transparent polymeric matrix is transparent in the visible spectra and not transparent (e.g., substantially absorbing) in the UV region (e.g., from about 200 nanometers to about 850 nanometers). Preferably, the light transparent polymeric matrix is at least 85% transparent in the visible spectra, at least 90% transparent, or at least 95% transparent corresponding to the wavelength(s) of the LED light emitted from the package.

In certain aspects, the curable coating is a one- or two-part-curable formulation comprising one or more precursor components. The precursor component is any one or more precursors that are suitable for and capable of providing an optically transparent coating for use in a lighting device. In one aspect, the precursor component comprises one precursor. In another aspect, the precursor component is comprised of a “two-part composition”. The precursor component provides for a cured or set coating optionally with other components. The cured or set coating prepared from the precursor components includes, sol-gels, gels, glasses, ceramics, cross-linked polymers, and combinations thereof.

Examples of cured or set matrixes formed from the one or more precursor components include, for example, one or more polymers and/or oligomers of silicones, e.g., polysiloxanes (e.g., polydialklysiloxanes (e.g., polydimethylsiloxane “PDMS”), polyalkylaryl siloxanes and/or polydiarylsiloxanes), epoxy resins, polyesters, polyarylesters, polyurethanes, cyclic olefinic copolymers (COC's), polynorbornenes, or hybrids and/or copolymers thereof, or such materials in combination with other components. Examples of LED coatings include, without limitation, LIGHT CAP® LED Casting Resin 9622 acrylated polyurethane, (Dynamax Corp., Torringtion Conn.); LPS-1503, LPS-2511, LPS-3541, LPS-5355, KER-6110, KER-6000, KER-6200, SCR-1016, ASP-1120, ASP-1042, KER-7030, KER-7080 (Shin-Etsu Chemical Co., Ltd, Japan); QSil 216, QSil 218, QSil 222, and QLE 1102 Optically Clear, 2-part Silicone coating (ACC Silicones, The Amber Chemical Company, Ltd.), United Kingdom); LS3-3354 and LS-3351 silicone coatings from NuSil Technology, LLC (Carpinteria, Calif.); TSE-3032, RTV615, (Momentive Potting Silicone, Waterford, N.Y.); Epic S7253 Polyurethane coating (Epic Resins, Palmyra, Wis.); OE-6630, OE-6631, OE-6636, OE-6336, OE-6450, OE-6652, OE-6540, OE-7630, OE-7640, OE-7620, OE-7660, OE-6370M, OE-6351, OE-6570, JCR-6110, JCR-6175, EG-6301, SLYGUARD silicone elastomers (Dow Corning, Midland, Mich.).

Preferably, the one- or two part-curable precursor component(s) are of low solvent content. More preferably, the one- or two part-curable precursor component(s) are essentially solvent-free. Essentially solvent-free is inclusive of no solvent and trace amounts of low volatility components, where trace amounts is solvent is present, but at an amount less than 5 weight percent, less than 1 weight percent, and less than 0.5 weight percent.

In one aspect, the coating comprises one or more silicon precursor components, which can comprise siloxane and/or polysiloxane. A number of polysiloxanes, with varying backbone structure are suitable for use as a precursor component. With reference to Equation (1), various forms of polysiloxanes, e.g. the M, T, Q, and D backbones, where R is, independently, alkyl or aryl, are presented:

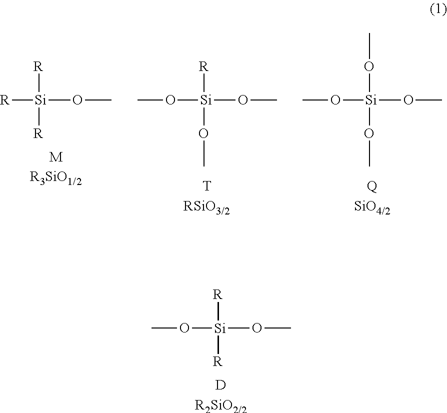

In various aspects, precursor components comprise one or more reactive silicone containing polymers (and/or oligomers or formulations comprising same). Such one or more reactive functional groups can be mixed with non-reactive silicone containing polymers. Examples of reactive silicone containing polymers with reactive groups, include for example, linear or branched polysiloxanes containing at least one acrylate, methacrylate, acrylamide, methacrylamide, fumarate, maleate, norbornenyl and styrene functional groups, and/or linear or branched polysiloxanes with multiple reactive groups such as Si—H (silicon hydride), hydroxy, alkoxy, amine, chlorine, epoxide, isocyanate, isothiocyanate, nitrile, vinyl, and thiol functional groups. Some specific examples of such linear or branched polysiloxanes include hydride-terminated, vinyl-terminated or methacrylate-terminated polydimethyl siloxanes, polydimethyl-co-diphenyl siloxanes and polydimethyl-co-methylphenylsiloxanes. The reactive groups can be located at one or both terminuses of the reactive silicone polymers, and/or anywhere along the backbone and/or branches of the polymer.

In one aspect, an exemplary example of a silicone precursor component comprises linear siloxane polymers, with dimethyl or a combination of methyl and phenyl chemical groups, with one or more reactive “R” chemical groups; where R is independently, hydrogen, vinyl or hydroxyl.

In another aspect, an exemplary example of a silicone precursor component comprises branched siloxane polymers, with dimethyl or a combination of methyl and phenyl chemical groups with one or more reactive “R” chemical groups, where R is independently hydrogen, vinyl or hydroxyl) associated with the precursor component.

In another aspect, an exemplary example of a silicone precursor component comprises linear siloxane polymers, with a combination of methyl, phenyl and hydroxyl or alkoxy chemical groups, with one or more reactive “R” chemical groups where R is hydrogen, vinyl or hydroxyl associated with the precursor component.

In another aspect, an exemplary example of a silicone precursor component comprises branched siloxanes, with any of methyl, phenyl and hydroxyl or alkoxy chemical groups, with one or more reactive “R” chemical groups where R is hydrogen, vinyl or hydroxyl associated with the precursor component.

In one aspect, a curable precursor component alone or with other material can be used specifically for forming coating for a LED lamp, for example, a LED lamp with a glass enclosure surrounding the LEDs and/or electrical components.

In one aspect, one or more polymers and/or oligomers of polysiloxanes are used. The one or more polymers and/or oligomers of polydialklysiloxanes (e.g., polydimethylsiloxane PDMS), polyalkylaryl siloxanes and/or polydiarylsiloxanes can comprise one or more functional groups selected from acrylate, methacrylate, acrylamide, methacrylamide, fumarate, maleate, norbornenyl and styrene functional groups, and/or polysiloxanes with multiple reactive groups such as hydrogen, hydroxy, alkoxy, amine, chlorine, epoxide, isocyanate, isothiocyanate, nitrile, vinyl, and thiol functional groups. Some specific examples of such polysiloxanes include vinyl-terminated-, hydroxyl-terminated, or methacrylate-terminated polydimethyl-co-diphenyl siloxanes and/or polydimethyl-co-methylhydro-siloxanes. In one aspect, the function group is located at one or both terminuses of the precursor component.

In one aspect, precursor components comprising or consisting essentially of silsesquioxane moieties and/or polysilsequioxane moieties can be employed for the coating. Polyhedral oligomeric silsesquioxanes and/or polysilsesquioxanes may be either homoleptic systems containing only one type of R group, or heteroleptic systems containing more than one type of R group. POSS-moieties are inclusive of homo- and co-polymers derived from moieties comprising silsesquioxanes with functionality, including mon-functionality and multi-functionality. Poly-POSS moieties encompass partially or fully polymerized POSS moieties as well as grafted and/or appended POSS moieties, end-terminated POSS moieties, and combinations.

Additional substances in the aforementioned coating or one or more precursor components providing the coating can be used, e.g., platinum catalyst, casting aids, defoamers, surface tension modifiers, functionalizing agents, adhesion promoters, crosslinking agents, viscosity stabilizers, other polymeric substances, and substances capable of modifying the tensile, elongation, optical, thermal, rheological, and/or morphological attributes of the precursor component or resulting coating.

The above compositions can be catalyzed by a platinum and/or rhodium catalyst component, which can be all of the known platinum or rhodium catalysts which are effective for catalyzing the reaction between silicon-bonded hydrogen groups and silicon-bonded olefinic groups.

### Light-Diffusing Particles/Light-Filtering Agents/Phosphors.

In certain aspects, the curable coating and/or one or more precursor components comprise one or more of a light-diffusing particles and/or light-filtering agents and/or phosphor. Thus, in any one or more of the aforementioned precursor component embodiments or resultant coating, a light-diffusing particles and/or light-filtering agents and/or phosphor can be added, incorporated therein, associated therewith, and/or combined. It is understood that any of the previously described coatings or layers can be used alone or be used with other coatings or layers, which can be deposited on and/or between other coatings or layers as described.

Light-diffusing particles comprise, for example, particles with an index of refraction. The light-transparent coating typically comprises a polymer matrix having a first index of refraction, and the light-diffusing particles have a second index of refraction differing from the polymer matrix by about 0.3 to about 0.1. In one aspect, the index of refraction of the light-diffusing particles can be between about 1.4-1.6. The average particle size of the light-diffusing particles can be between about 1 nanometer (nanoparticles) to about 500 microns. In preferred embodiments, the light-diffusing particles has an average particle size distribution between one micron and 25 micron. The light-diffusing particles can be added alone or in combination with other components such as the phosphor or light-filtering agent and added to the curable coating or to either part (Part A and/or Part B) or both parts of a two-part curable coating. The light-diffusing particles can be present between 0.1 to 15 weight percent, between about 0.5 to 12 weight percent, between about 1 to about 10 weight percent, or between about 1 to about 7 weight percent of the polymer matrix. In certain aspects, light-diffusing particles can be present at about 1.5 to about 2.5 weight percent.

Examples of light-diffusing particles include, without limitation, fumed silica, fused quartz, fused silica, precipitated silica and/or other non-crystalline forms of silicon dioxide (SiO₂), which is also referred to generally as “silica.” The particular name reflecting the process used to make them, e.g.,: fused silica/fused quartz primarily prepared by electrical/melting process; fumed silica by flame process of silicate feed stocks, and precipitated silica by wet chemical reaction. Typically these forms of “silica” contain impurities. The typical impurities depend on the starting material and the process used. In one aspect, the presence of trace impurities does not substantially affect performance. In one aspect, the light diffusing particles are silica particles that are chemically treated to be hydrophobic or hydrophilic. Other light-diffusing particles suitable for use in the present disclosure include, for example, particles of sodium chloride, poly(methyl)acrylate, polycarbonate, and the like.

Light filtering agents may be used to provide a spectral notch. A spectral notch occurs is when a portion of the color spectrum of light passing through a medium is attenuated, thus forming a “notch” when the light intensity of the light is plotted against wavelength. Depending on the type or composition of glass or other spectral notch material used to form or coat the enclosure, the amount of light filtering agent present, and the amount and type of other trace substances in the enclosure, the spectral notch can occur between the wavelengths of 520 nm and 605 nm. In some embodiments, the spectral notch can occur between the wavelengths of 565 nm and 600 nm. In other embodiments, the spectral notch can occur between the wavelengths of 570 nm and 595 nm. Such systems are disclosed in U.S. patent application Ser. No. 13/341,337, filed Dec. 30, 2011, titled “LED Lighting Using Spectral Notching” which is incorporated herein by reference in its entirety. Examples of light filtering agents include, one or more lanthanide elements or lanthanide compounds and equivalents coated on or doped (incorporated in) the enclosure, the light-filtering agent is present at a loading sufficient to provide spectral notching. In other aspects, the light-filtering agent can be powder-coated on the interior surface of the enclosure, or the enclosure can be doped with the I light-filtering agent or be contained in at least a portion of the thickness of the enclosure separating the interior and exterior surfaces of the enclosure. In yet other examples, the light-filtering agent can be included in a polymer matrix as described above or as disclosed in co-assigned U.S. application Ser. No. 13/837,379, filed Mar. 15, 2013, entitled “RARE EARTH OPTICAL ELEMENTS FOR LED LAMP,” which is incorporated herein by reference in its entirety. In other aspects, the light-filtering agent can be coated on the interior or exterior of the enclosure, independently or in combination with the coating comprising light diffusing particles or other coatings or layers.

Depending on the LEDs used, the enclosure may be a glass or brittle ceramic or plastic, and/or doped with a rare earth (or lanthanide) compound or element, for example, a lanthanide oxide or other dichroic material, for example alexandrite (BeAl₂O₄).

In one aspect, the light-filtering agent is a lanthanide compound or element or compound of a rare earth element (collectively “REE”), such as an oxide, nitride, e.g., neodymium oxide (or neodymium sesquioxide). Other light-filtering agents can be used, such as, neodymium(III) nitrate hexahydrate (Nd(NO₃)₃.6H₂O); neodymium(III) acetate hydrate (Nd(CH₃CO₂)₃.xH₂O); neodymium(III) hydroxide hydrate (Nd(OH)₃); neodymium(III) phosphate hydrate (NdPO₄.xH₂O); neodymium(III) carbonate hydrate (Nd₂(CO₃)₃.xH₂O); neodymium(III) isopropoxide (Nd(OCH(CH₃)₂)₃); neodymium(III) titanante (Nd₂O₃ titanate.xTiO₂); neodymium(III) chloride hexahydrate (NdCl₃.6H₂O); neodymium(III) fluoride (NdF₃); neodymium(III) sulfate hydrate (Nd₂(SO₄)₃.xH₂O); neodymium(III) oxide (Nd₂O₃); erbium(III) nitrate pentahydrate (Er(NO₃)₃5.H₂O); erbium(III) oxalate hydrate (Er₂(C₂O₄)₃.xH₂O); erbium(III) acetate hydrate (Er(CH₃CO₂)₃.xH₂O); erbium(III) phosphate hydrate (ErPO₄.xH₂O); erbium(III) oxide (Er₂O₃); Samarium(III) nitrate hexahydrate (Sm(NO₃)₃.6H₂O); Samarium(III) acetate hydrate (Sm(CH₃CO₂)₃.xH₂O); Samarium(III) phosphate hydrate (SmPO₄.xH₂O); Samarium(III) hydroxide hydrate (Sm(OH)₃.xH₂O); samarium(III) oxide (Sm₂O₃); holmium(III) nitrate pentahydrate (Ho(NO₃)₃.5H₂O); holmium(III) acetate hydrate ((CH₃CO₂)₃Ho.xH₂O); holmium(III) phosphate (HoPO₄); and holmium(III) oxide (Ho₂O₃). Other REE compounds, including organometallic compounds of neodymium, didymium, dysprosium, erbium, holmium, praseodymium and thulium can be used.

Thus the light filtering agent can be one or more REE's coated on one or both sides of a smooth or diffuse enclosure surface, doped into the enclosure, included in polymer coatings on one or both sides of the smooth or diffuse enclosure, or be included in an optically transmissive media contained in the enclosure so as to provide light filtering of the LED emitted light, or can be used in combination with other optical functionality provided by other materials and/or coatings. Certain REE's can be used to selectively filter light from the one or more LED's and/or improve color rendering index (CRI).

Thus, with the enclosure being transmissive of light, due to the filtering (e.g., the lanthanide compound or element) from the coating or layer thereon, light passing through the enclosure of the LED lamp is filtered prior to interacting with the coating comprising light-diffusing particles so that the light exiting the enclosure exhibits a spectral notch and is diffused to provide an improved luminous intensity distribution LED lamp. Likewise, in another embodiment, with the enclosure being transmissive of light and having a diffuse interior surface (e.g., etched or frosted), due to spectral notch filtering (e.g., via the lanthanide compound or element interiorly-coated on or doped in the enclosure) light emitted by the LED and passing through the thickness of the enclosure of the LED lamp is at least partially filtered and at least partially diffused prior to interacting with the coating comprising light-diffusing particles so that the light exiting the enclosure exhibits a spectral notch and is further diffused to provide an improved luminous intensity distribution LED lamp.

By way of example, the enclosure can be configured such that a rare earth (or lanthanide) compound or element is deposited on the surface of the enclosure, for example, the interior surface or exterior surface using conventional techniques such as powder coating etc. In one embodiment, the rare earth (or lanthanide) compound or element is deposited only on the interior surface of the enclosure or the enclosure is doped (e.g., incorporated within the enclosure thickness), and the light-diffusing coating deposited on the exterior of the enclosure, the coating and the rare earth (or lanthanide) compound or element separated by the thickness of the enclosure In another embodiment, the rare earth (or lanthanide) compound or element is deposited only on an etched (chemically or sandblasted) interior surface of the enclosure or the enclosure is doped (e.g., incorporated within the enclosure thickness), and the coating deposited on the exterior of the enclosure, the coating and the rare earth (or lanthanide) compound or element separated by the thickness of the enclosure. Coatings or layers of the light-diffusing particles can be coated on or layered with other coating, e.g., containing phosphors, light-filtering agents, etc. as desired to provide particular luminous properties, color, color rendering index, etc.

Phosphors include, for example, commercially available YAG:Ce, although a full range of broad yellow spectral emission is possible using conversion particles made of phosphors based on the (Gd,Y)₃(Al,Ga)₅O₁₂:Ce system, such as the Y₃Al₅O₁₂:Ce (YAG). Other yellow phosphors that can be used for white-light emitting LED chips include, for example: Tb₃₋ₓREₓO₁₂:Ce(TAG), where RE is Y, Gd, La, Lu; or Sr_{2-x-y}BaₓCa_{y}SiO₄:Eu.

Some phosphors appropriate for the LED lamp disclosed can comprise, for example, silicon-based oxynitrides and nitrides for example, nitridosilicates, nitridoaluminosilicates, oxonitridosilicates, oxonitridoaluminosilicates, and sialons. Some examples include: Lu₂O₃:Eu³⁺(Sr₂₋ₓLaₓ)(Ce₁₋ₓEuₓ)O₄ Sr₂Ce₁₋ₓEuₓO₄ Sr₂,EuₓCeO₄SrTiO₃:Pr³⁺,Ga³⁺CaAlSiN₃:Eu²⁺Sr₂Si₅N₈:Eu²⁺ as well as SrₓCa₁₋ₓS:EuY, where Y is halide; CaSiAlN₃:Eu; and/or Sr_{2-y}Ca_{y}SiO₄:Eu. Other phosphors can be used to create color emission by converting substantially all light to a particular color. For example, the following phosphors can be used to generate green light: SrGa₂S₄:Eu; Sr_{2-y}Ba_{y}SiO₄:Eu; or SrSi₂O₂N₂:Eu.

By way of example, each of the following phosphors exhibits excitation in the UV emission spectrum, provides a desirable peak emission, has efficient light conversion, and has acceptable Stokes shift, for example: Yellow/Green: (Sr,Ca,Ba)(Al,Ga)₂S₄:Eu²⁺Ba₂(Mg,Zn)Si₂O₂:Eu²⁺Gd_{0.46}Sr_{0.31}Al_{1.23}OₓF_{1.38}:Eu²⁺_{0.06}(Ba_{1-x-y}SrₓCa_{y})SiO₄:EuBa₂SiO₄:EU²⁺.

The lighting device can comprise solid-state light sources arranged with one or more phosphors so as to provide at least one of blue-shifted yellow (BSY), blue-shifted green (BSG), blue-shifted red (BSR), green-shifted red (GSR), and cyan-shifted red (CSR) light. Thus, for example, a blue LED with a yellow emitting phosphor radiationally coupled thereto and absorbing some of the blue light and emitting yellow light provides for a device having BSY light. Likewise, a blue LED with a green or red emitting phosphor radiationally coupled thereto and absorbing some of the blue light and emitting green or red light provides for devices having BSG or BSR light, respectively. A green LED with a red emitting phosphor radiationally coupled thereto and absorbing some of the green light and emitting red light provides for a device having GSR light. Likewise, a cyan LED with a red emitting phosphor radiationally coupled thereto and absorbing some of the cyan light and emitting red light provides for a device having CSR light.

A lighting system using the combination of BSY and red LED devices referred to above to make substantially white light can be referred to as a BSY plus red or “BSY+R” system. In such a system, the LED devices used include LEDs operable to emit light of two different colors. In one example embodiment, the LED devices include a group of LEDs, wherein each LED, if and when illuminated, emits light having dominant wavelength from 440 to 480 nm. The LED devices include another group of LEDs, wherein each LED, if and when illuminated, emits light having a dominant wavelength from 605 to 630 nm. A phosphor can be used that, when excited, emits light having a dominant wavelength from 560 to 580 nm, so as to form a blue-shifted-yellow light with light from the former LED devices. In another example embodiment, one group of LEDs emits light having a dominant wavelength of from 435 to 490 nm and the other group emits light having a dominant wavelength of from 600 to 640 nm. The phosphor, when excited, emits light having a dominant wavelength of from 540 to 585 nm. A further detailed example of using groups of LEDs emitting light of different wavelengths to produce substantially white light can be found in issued U.S. Pat. No. 7,213,940, which is incorporated herein by reference.

In certain aspects, the extent of light diffusion by the diffuse interior surface of the enclosure is less than or approximately equal to that provided by the coating comprising the light-diffusing particles. In other aspects, the extent of light diffusion by the diffuse interior surface of the enclosure is considerably less than that provided by the coating comprising the light-diffusing particles.

The thickness of the enclosure in any of the aforementioned embodiments can be constant or variable, or can be gradient in thickness in one or more portions of the enclosure, for example thicker or thinner at low angle positions about the enclosure relative to the LED arrangement.

### Led Lamp Examples

LED lamps of any variety and/or shape can be used in the practice of the present disclosure. More particularly, LED lamps with frangible enclosures, such as glass enclosures, may benefit from the present disclosure.

By way of example, LED lamps are disclosed as exemplary lighting devices suitable for the present disclosure. The lamp may also comprise a directional lamp such as BR-style lamp or a PAR-style lamp where the LEDs may be arranged to provide directional light, with or without reflecting surfaces. In other embodiments, the LED lamp can have any shape, including standard and non-standard shapes.

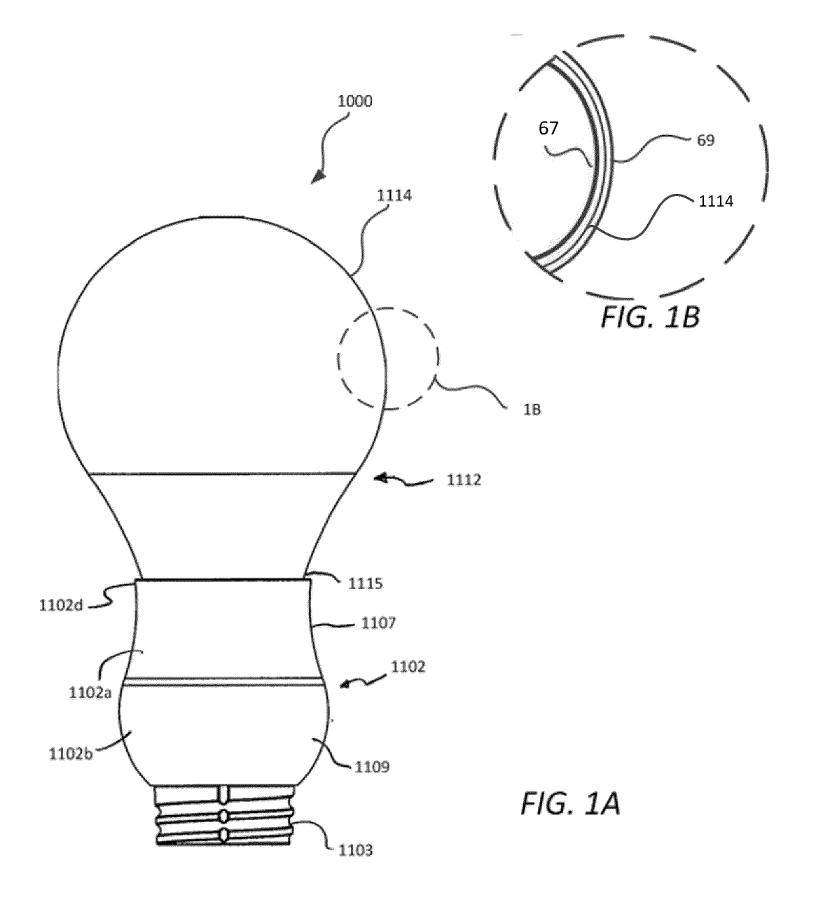

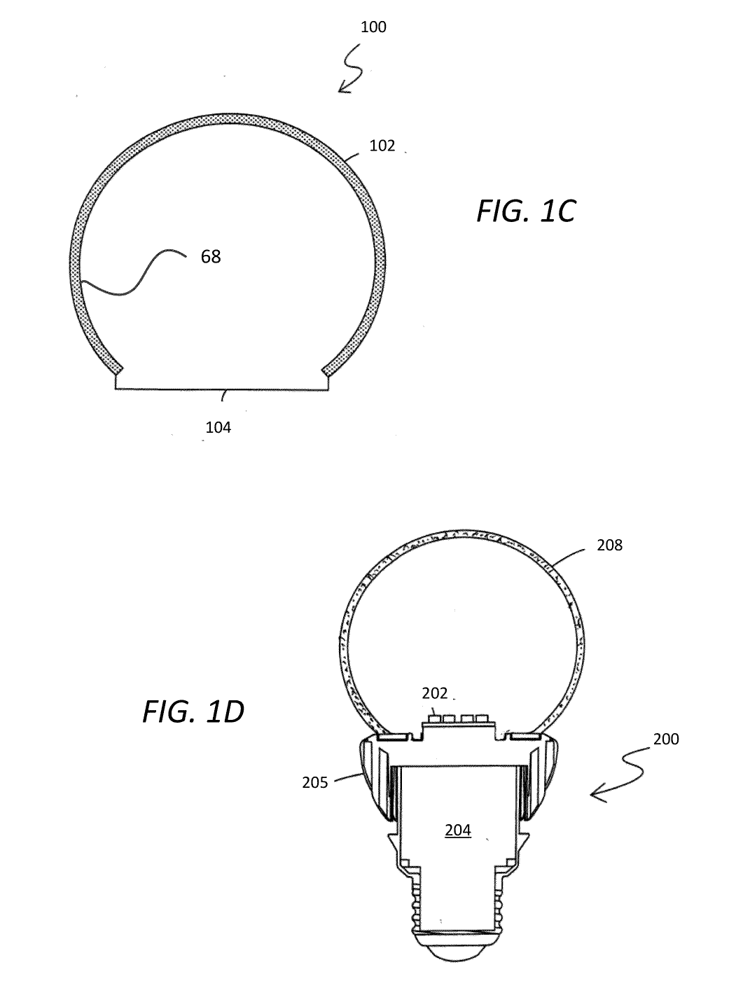

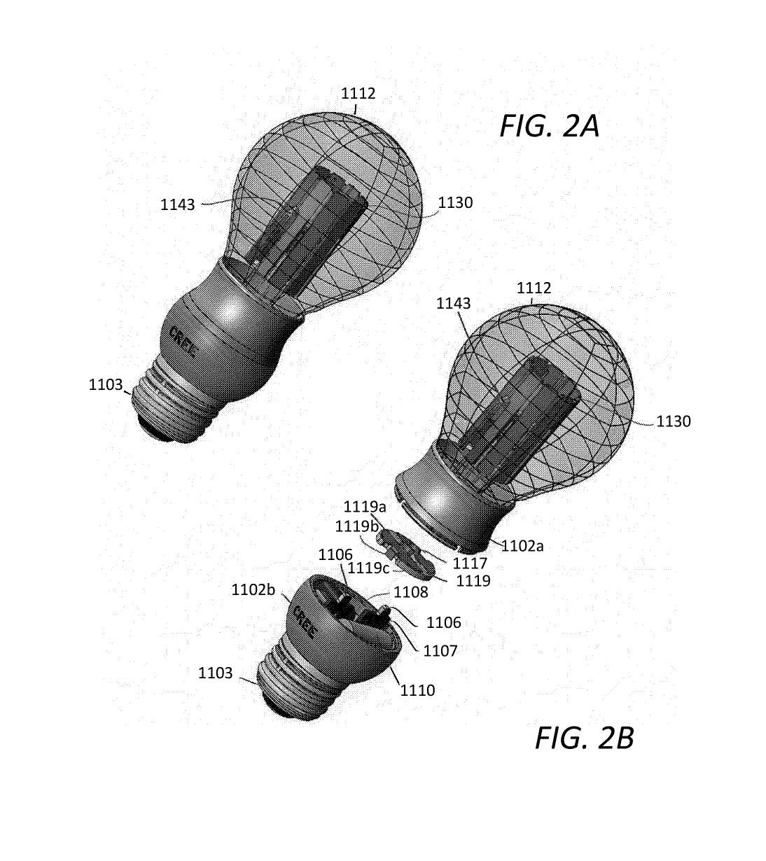

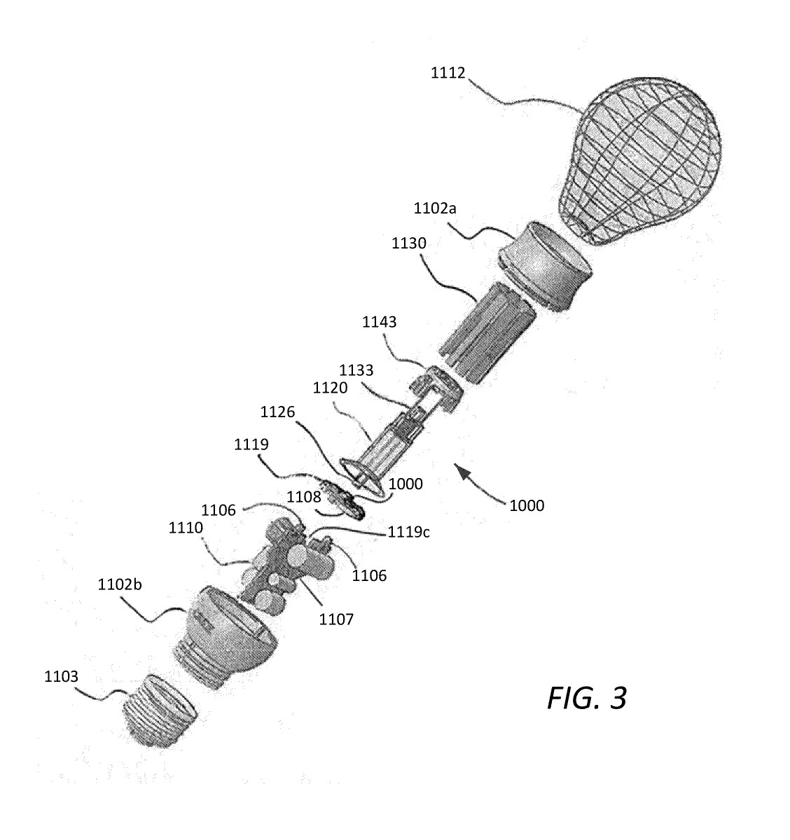

Thus, with reference to FIGS. 1A, 1B, 1C, 1D, 2A, 2B, and 3, lamp 1000 having a generally globe shaped enclosure 1114, comprises a solid-state lamp comprising a LED assembly 1130 with light emitting LEDs 1127. Multiple LEDs 1127 can be used together, forming an LED array 1128. The LEDs 1127 can be mounted on or fixed within the lamp in various ways. In at least some example embodiments, a submount (not shown) is used. In the present disclosure the term “submount” is used to refer to the support structure that supports the individual LEDs or LED packages and in one embodiment comprises a PCB although it may comprise other structures such as a lead frame extrusion or the like or combinations of such structures. The LEDs 1127 in the LED array 1128 include LEDs which may comprise an LED die disposed in an encapsulant such as silicone, and LEDs which may be encapsulated with a phosphor to provide local wavelength conversion when various options for creating white light are discussed. A wide variety of LEDs and combinations of LEDs may be used in the LED assembly 1130. FIG. 1B is a partial exploded view of enclosure 1114 of lamp 1000 having coating 69 on outer surface thereof. In certain embodiments diffuse interior enclosure surface 67 can optionally be employed as described herein. Coating 69 can be optically clear and/or transparent and can be deposited on the exterior surface of enclosure 1114.

In some embodiments, the LED bulb 1000 is equivalent to a 60 Watt incandescent light bulb. In one embodiment of a 60 Watt equivalent LED bulb, the LED assembly 1130 comprises an LED array 1128 of 20 XLamp® XT-E High Voltage white LEDs manufactured by Cree, Inc., where each XLamp® XT-E LED has a 46 V forward voltage and includes 16 DA LED chips manufactured by Cree, Inc. and configured in series. The XLamp® XT-E LEDs may be configured having LEDs arranged in series, for a total of greater than 200 volts, e.g. about 230 volts, across the LED array 1128. In another embodiment of a 60 Watt equivalent LED bulb, 20 XLamp® XT-E LEDs are used where each XT-E has a 12 V forward voltage and includes DA LED chips arranged in series, for a total of about 240 volts across the LED array 1128 in this embodiment. In some embodiments, the LED bulb 1000 is equivalent to a 40 Watt incandescent light bulb. In such embodiments, the LED array 1130 may comprise 10 XLamp® XT-E LEDs where each XT-E includes 16 DA LED chips configured in series. The 10 46V XLamp® XT-E® LEDs may be configured in two parallel strings where each string has five LEDs arranged in series, for a total of about 230 volts across the LED array 1128. In other embodiments, different types of LEDs are possible, such as XLamp® XB-D LEDs manufactured by Cree, Inc. or others. Other arrangements of chip on board LEDs and LED packages may be used to provide LED based light equivalent to 40, 60 and/or greater other watt incandescent light bulbs, at about the same or different voltages across the LED array 1128. In other embodiments, the LED assembly 1130 can have different shapes, such as triangular, square and/or other polygonal shapes with or without curved surfaces.

Still referring to FIGS. 1-3, a modified base 1102 is shown comprising a two part base having an upper part 1102a that is connected to enclosure 1112 and a lower part 1102b that is joined to the upper part 1102a. An Edison screw 1103 is formed on the lower part 1102b for connecting to an Edison socket. The base 1102 may be connected to the enclosure 1112 by any suitable mechanism including adhesive, welding, mechanical connection or the like. The lower part 1102b is joined to the upper part 1102a by any suitable mechanism including adhesive, welding, mechanical connection or the like. The base 1102 may be made reflective to reflect light generated by the LED lamp. The base 1102 has a relatively narrow proximal end 1102d that is secured to the enclosure 1112 where the base gradually expands in diameter from the proximal end to a point P between the proximal end and the Edison screw 1103. By providing the base 1102 with a larger diameter at an intermediate portion thereof the internal volume of the base is expanded over that provided by a cylindrical base. As a result, a larger internal space 1105 is provided for receiving and retaining the power supply 1111 and drivers 1110 in the base. From point P the base gradually narrows toward the Edison screw 1103 such that the diameter of the Edison screw may be received in a standard Edison socket. The exterior surface of the base 1102 is formed by a smooth curved shape such that the base uniformly reflects light outwardly. Providing a relatively narrow proximal end 1102d prevents the base 1102 from blocking light from being projected generally downward and the concave portion 1107 reflects the light outwardly in a smooth pattern. The smooth transition from the narrower concave portion 1107 to the wider convex portion 1109 also provides a soft reflection without any sharp shadow lines.

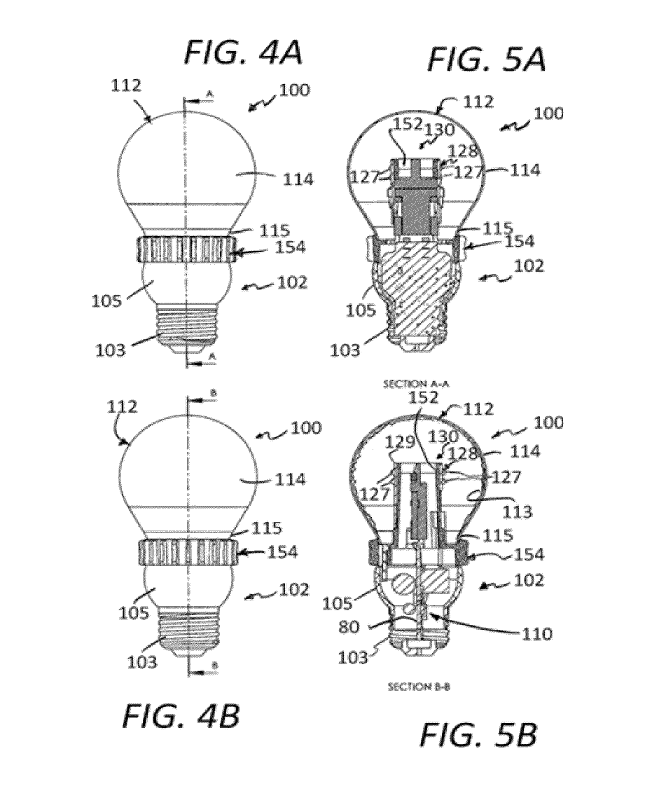

FIGS. 4A, 4B, 5A, and 5B show, collectively, another exemplary LED lamp to illustrate an embodiment of a lamp 100 that, among other things, can serve as a replacement for an incandescent bulb. This embodiment makes use of similar components or features which have already been described, however, the heat sink element 154 and/or the housing portion 105 is unique to that of LED lamp 1000 discussed above. Lamp 100 may be used as an A-series lamp with an Edison base 102, more particularly; lamp 100 is designed to serve as a solid-state replacement for an A19 incandescent bulb. The Edison base 102 as shown and described herein may be implemented through the use of an Edison connector 103 and a plastic form. The LEDs 127 in the LED array 128 may comprise an LED die disposed in an encapsulant such as silicone, and LEDs which are encapsulated with a phosphor to provide local wavelength conversion when various options for creating white light are desired. The LEDs 127 of LED array 128 are mounted on a submount 129 and are operable to emit light when energized through an electrical connection. In some embodiments, a driver or power supply may be included with the LED array on the submount. In some cases the driver may be formed by components on a printed circuit board or “PCB” 80. While a lamp having the size and form factor of a standard-sized household incandescent bulb is shown, the lamp may have other the sizes and form factors. For example the lamp may be a PAR-style lamp such as a replacement for a PAR-38 incandescent bulb.

Enclosure 112 is, in some embodiments, made of a frangible material, such as glass, quartz, borosilicate, silicate, other glass or other suitable material. The enclosure may be of similar shape to that commonly used in household incandescent bulbs. In some embodiments, the glass enclosure is coated on the inside with silica 113 or other diffusive material such as refractory oxides, providing a diffuse scattering layer that produces a more uniform far field pattern. The enclosure may also be etched, frosted and coated with the protective layer as disclosed herein. Alternatively, the surface treatment may be omitted and a clear enclosure may be provided. It should also be noted that in this or any of the embodiments shown here, the optically transmissive enclosure or a portion of the optically transmissive enclosure could be coated or impregnated with phosphor or a diffuser. The glass enclosure 112 may have a traditional bulb shape having a globe shaped main body 114 that tapers to a narrower neck 115.

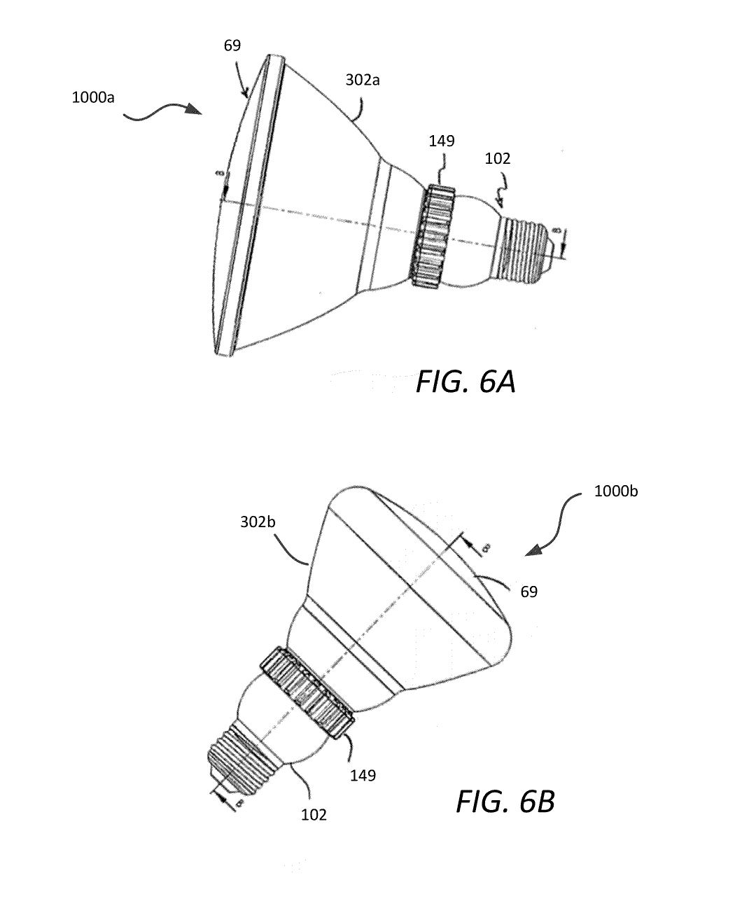

A lamp base 102 such as an Edison base functions as the electrical connector to connect the lamp 100 to an electrical socket or other connector. Depending on the embodiment, other base configurations are possible to make the electrical connection such as other standard bases or non-traditional bases. Base 102 may include the electronics 110 for powering lamp 100 and may include a power supply and/or driver and form all or a portion of the electrical path between the mains and the LEDs. Base 102 may also include only part of the power supply circuitry while some smaller components reside on the submount. With the embodiment of FIG. 6, as with many other embodiments of the present disclosure, the term “electrical path” can be used to refer to the entire electrical path to the LED array 128, including an intervening power supply disposed between the electrical connection that would otherwise provide power directly to the LEDs and the LED array, or it may be used to refer to the connection between the mains and all the electronics in the lamp, including the power supply. The term may also be used to refer to the connection between the power supply and the LED array. Electrical conductors run between the LED assembly 130, which seats against the heat conducting portion 152 to ensure good thermal conductivity between these elements, and the lamp base 102 to carry both sides of the supply to provide critical current to the LEDs 127.

The LED assembly 130 may be implemented using a printed circuit board (“PCB”) and may be referred by in some cases as an LED PCB. In some embodiments the LED PCB comprises the submount 129. The lamp 100 comprises a solid-state lamp comprising a LED assembly 130 with light emitting LEDs 127. Multiple LEDs 127 can be used together, forming an LED array 128. The LEDs 127 can be mounted on or fixed within the lamp in various ways. In at least some example embodiments, a submount 129 is used. The LEDs 127 in the LED array 128 include LEDs which may comprise an LED die disposed in an encapsulant such as silicone, and LEDs which may be encapsulated with a phosphor to provide local wavelength conversion. A wide variety of LEDs and combinations of LEDs may be used in the LED assembly 130 as described herein. The LEDs 127 of the LED array 128 are operable to emit light when energized through an electrical connection. An electrical path runs between the submount 129 and the lamp base 102 to carry both sides of the supply to provide critical current to the LEDs 127.

Still referring to FIGS. 4A-5B, in some embodiments, a driver and/or power supply are included with the LED array 128 on the submount 129. In other embodiments the driver and/or power supply are included in the base 102 as shown. The power supply and drivers may also be mounted separately where components of the power supply are mounted in the base 102 and the driver is mounted with the submount 129 in the enclosure 112. Base 102 may include a power supply or driver and form all or a portion of the electrical path between the mains and the LEDs 127. The base 102 may also include only part of the power supply circuitry while some smaller components reside on the submount 129. In some embodiments any component that goes directly across the AC input line may be in the base 102 and other components that assist in converting the AC to useful DC may be in the glass enclosure 112. In one example embodiment, the inductors and capacitor that form part of the EMI filter are in the Edison base.

In some embodiments a gas movement device may be provided within the enclosure 112 to increase the heat transfer between the LEDs 127 and LED assembly 130 and heat sink 149. The movement of the gas over the LED assembly 130 moves the gas boundary layer on the components of the LED assembly 130. In some embodiments the gas movement device comprises a small fan. The fan may be connected to the power source that powers the LEDs 127. While the gas movement device may comprise an electric fan, the gas movement device may comprise a wide variety of apparatuses and techniques to move air inside the enclosure such as a rotary fan, a piezoelectric fan, corona or ion wind generator, synjet diaphragm pumps or the like.

The LED assembly 130 comprises a submount 129 arranged such that the LED array 128 is substantially in the center of the enclosure 112 such that the LED's 127 are positioned at the approximate center of enclosure 112. As used herein the term “center of the enclosure” refers to the vertical position of the LEDs in the enclosure as being aligned with the approximate largest diameter area of the globe shaped main body 114. In one embodiment, the LED array 128 is arranged in the approximate location that the filament is disposed in a standard incandescent bulb.

FIG. 6A and FIG. 6B are embodiments of an exemplary LED lamp, more specifically, lamps different from an omnidirectional lamp such as an A19 replacement bulb discussed above. The BR or PAR bulbs shown in FIG. 6A and FIG. 6B, the light is emitted in a directional pattern rather than in an omnidirectional pattern. Standard BR or PAR type bulbs are reflector bulbs that reflect light in a directional pattern; however, the beam angle is not tightly controlled and may be up to about 90-100 degrees or other fairly wide angles. With reference to FIG. 6A, a perspective view of a directional lamp 1000a, such as a replacement for a parabolic aluminized reflector (“PAR”) incandescent bulb, is shown. Thus, the bulbs (1000a, 1000b) shown in FIGS. 6A-6B may be used as a solid state replacements for BR-type and PAR-typer reflector type bulbs or other similar bulbs. The bulbs of FIGS. 6A-6B include heat sink 149 and enclosures (302a, 302b). For example, lamp 1000a includes an LED array on submount (not shown), disposed within an outer reflector enclosed within enclosure 302a. A frangible glass or frangible plastic lens portion 702 can be coated with the coating 69 as disclosed herein. A power supply (not shown) can be housed in base portion 310 of lamp 1000a. Lamp 1000a may include an Edison base 102. A reflector (not shown) and lens portion 702 with coating 69 may together form the optically transmissive enclosure 302a for the lamp, albeit light transmission in this case is directional. Note that a lamp like lamp 1000a could be formed with a unitary enclosure, formed as an example from frangible material such as glass, appropriately shaped and silvered or coated on an appropriate portion to form a directional, optically transmissive enclosure. Lamp 1000a may include an environment, such as one or more inert gases, within the optically transmissive enclosure to provide thermal coupling to the LED array and any power supply components. With reference to FIG. 6B, lamp 1000b, can also be configured as a directional LED lamp, suitable for replacement of a BR-30 incandescent bulb. Coating 69 can be arranged on the entirety of the exterior surface of the enclosures 302a, 302b, and/or can be banded or layered about a portion of the enclosure as discussed further below.

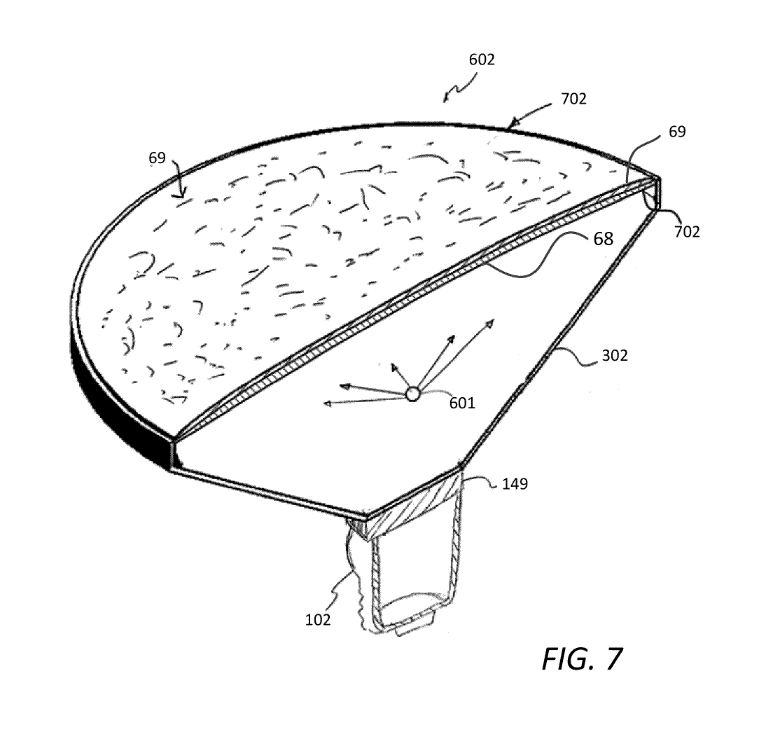

FIG. 7 depicts a cross-sectional view of a BR or PAR type bulb 602 showing an LED element 601 emitting essentially omnidirectional light to enclosure 302 (which may comprise reflecting elements) through frangible section 702 of enclosure 302 having coating 69 deposited thereon. Interior 68 of enclosure 302 can optionally be may diffuse. Enclosure 302 can be provided with or be configured to contain a first environment, for example, one or more inert gases as an environment, for improved cooling, a specific CRI, or other function.

### Methods

Methods of providing improved luminous intensity distribution of a light emitting diode (LED) lamp are provided by using the presently disclosed light transparent coating with light diffusing particles. In a first aspect, the method comprises coating an enclosure surrounding one or more LEDs, the coating comprising light-diffusing particles in an amount sufficient to diffuse light emitted by the one or more LEDs. The enclosure has an interior surface separated from an exterior surface by a thickness. The interior surface of the enclosure can be smooth and optionally, the thickness can contain a light filtering agent doped in or as a coating. Other coatings with other materials for modifying the optical and luminous properties of the LED lamp can be used. This configuration provides a normalized luminous intensity of 0.75 to 1.25 maintained over the range of 0 to 135 degrees of angle of measurement.

In another aspect, light emitted by one or more LEDs capable of emitting light of one or more wavelengths is diffused by passing the one or more wavelengths of light through a coating deposited on an exterior surface of an enclosure that at least partially surrounding the one or more LEDs. The interior surface of the enclosure can be diffuse or otherwise roughened, e.g., etched or sandblasted or frosted so as to diffuse light. As discussed above, the coating can comprise a transparent polymer matrix and an amount of light-diffusing particles. In this embodiment, the method provides a normalized luminous intensity of between 0.75 to 1.25 maintained over a range of 0 to 135 degrees of angle of measurement.

In another aspect, the method further comprises absorbing at least a portion of the light emitted by the one or more LEDs before passage through the coating using one or more REE's that can be deposited on an interior surface of the enclosure, or incorporated or doped within the thickness of the enclosure. The method can further comprise diffusing at least a portion of the light emitted by the one or more LEDs before passage through the coating. In one aspect, this is done by using an etched or frosted interior surface of the enclosure.

In yet another aspect, alone or in combination with the above aspects, the method can comprise diffusing at least a portion of the light emitted by the one or more LEDs before passage through the coating using an etched or frosted interior surface of the enclosure and absorbing at least a portion of the light emitted by the one or more LEDs before passage through the coating using one or more light filtering agents deposited on an interior surface of the enclosure or incorporated or doped within the thickness of the enclosure.

To further explain the advantageous features of coating 69 including luminous intensity distribution properties of the lamp 1000, an embodiment of a method of coating a lamp will be described. Any coating method useful for materials of similar viscosity to that of the precursor components (mixed or separately) can be used. For example, each part of a two-part composition can be separately handled, for example, in a spray apparatus, or they can be combined prior to or subsequent to being sprayed, atomized, flowed, brushed, or rolled on the surface of the LED lamp. In other example, the LED lamp can be dip coated into a bath of one or more of the precursor components. The precursor components can be mixed together or can be configured in separate baths for sequential dipping of the LED lamp. In another aspect, the LED lamp can be cascade-coated by passing through one or more flowing streams of one or more precursor components.

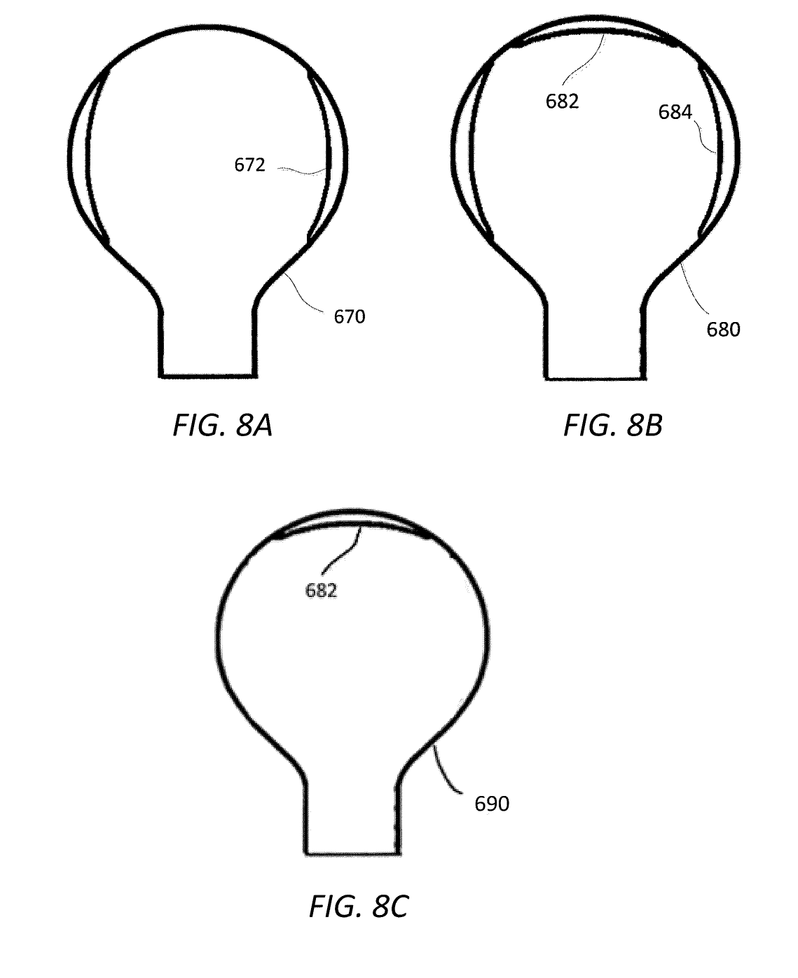

In another aspect, a combination of coating processes can be used, for example, a dip or cascade coating in combination with a spray coating. In one aspect, as depicted in FIGS. 8A-C, various enclosures 670, 680, 690 can be prepared, for example, by a spray coating process for providing one or more “bands” 672, 682, 684, of one or more coatings on the interior or exterior surface of the enclosure 670, 680, 690, so as to provide a variable (or a defined) thickness of coating about the enclosure, for example, the widest sections and/or the apex of the enclosure furthest from the Edison socket can be banded to improve luminous intensity distribution. The “bands” can independently contain one or more of light-diffusing particles and/or phosphors and/or be a variable thickness or of substantially identical thickness, and/or have varying or similar concentration of light-diffusing particles. Likewise, banding of the interior surface of the enclosure (diffuse surface) can also be employed alone or in combination with banding of the coating present on the exterior surface of the enclosure.

In certain aspects, the viscosity of the one or more precursor components is provided within a target range. In this aspect, the one or more precursor components can be solvent-free. Thus, in one aspect, the viscosity of the one or more precursor components is chosen to be between about 500 to about 20,000 centipoise, or about 750 to about 15,000 centipoise, or about 1000 to about 12,000 centipoise, or about 1500 to about 10,000 centipoise, or about 2000 to about 8,000 centipoise. In one aspect, the viscosity of the one or more precursor components is chosen to be between about 3,000 to about 7,000 centipoise, for example, to allow a continuous dip coating process of LED lamps.

However, the viscosity of such solvent-free silicone elastomer mixtures increases from an initial viscosity, rapidly increasing at room temperature and becoming too viscous to be useable after a short time (3-24 hrs), making large-scale production processes difficult, in-efficient, and costly.

Thus, in an embodiment, one or more viscosity stabilizers can be used in combination with the one or more precursor components to maintain a target viscosity for a time interval at a temperature above that of a set/cure/gel temperature (a temperature capable of setting, curing, or gelling of the precursor components in the absence of the viscosity controlling agent). Maintaining a viscosity within a range is useful to control the coating thickness and/or coating weight about the LED lamp. The viscosity controlling agent can be used so that the temperature of the one or more precursor components can be maintained at an elevated temperature, e.g., any temperature below the set/cure temperature to alter the viscosity and thus provide for control of the thickness and/or weight of coating applied.

After the coating and/or precursor components are deposited on the LED lamp, the coating can be cured, or the cure process can be accelerated, by using heat and/or light to initiate and/or accelerate the crosslinking or coupling of the precursor components or to overcome the viscosity stabilizer.

### EXAMPLES

Luminous Intensity distribution measurement were performed per IES LM-79-08 Electrical and Photometric Measurements of Solid-State Lighting Products. Thus, fine ground silica powder, such as MIN-U-SIL from US Silica, was mixed and suspended in a 2-part silicone coating, which was coated on a test sample LED lamp, e.g., a commercially available 6-Watt (40W) A19 Warm White (2700K) Dimmable LED Light Bulb manufactured by Cree.

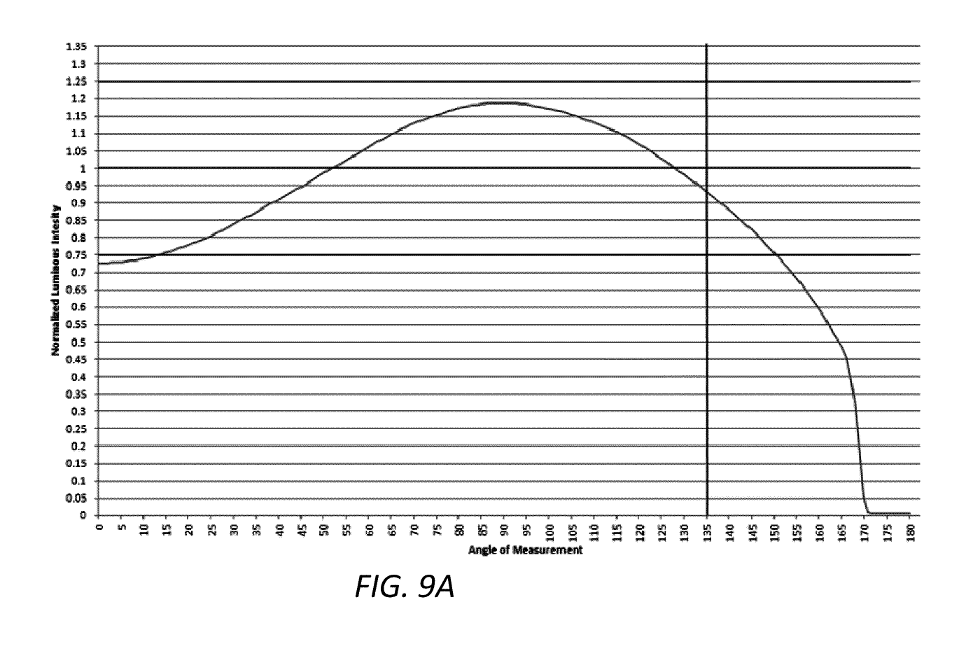

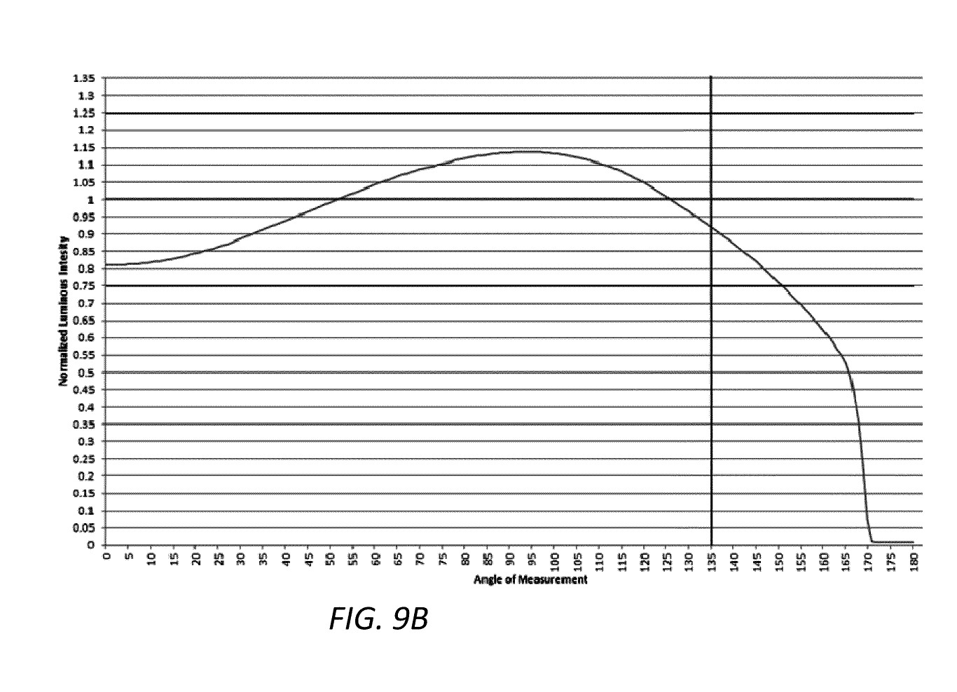

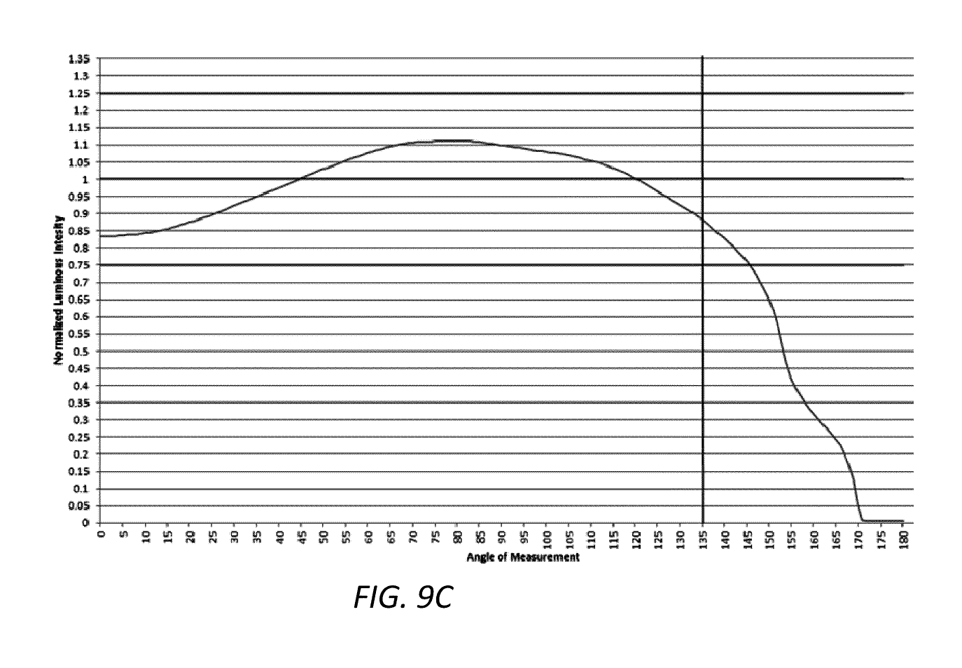

The ground silica powder provided a diffuse medium capable of diffracting light, which improved the luminous intensity distribution as shown in FIGS. 9A-9C, where FIG. 9A represents an enclosure without the presently disclosed coating; FIG. 9B represents the first concentration of light-diffusing particles, and FIG. 9C represents a second concentration of light-diffusing particles (greater than the first concentration). As can be seen from the graphs of FIGS. 9A-9C, varying the concentration level of the silica powder changed the amount of diffusion achieved in the coating as well as providing a more linear luminous distribution across the angle of incidence measured. Diffusion level can be adjusted to achieve desired light distribution based on a number of parameters, including the arrangement and selection of LEDs, glass used for the enclosure and the presence or absence of light filtering agents, the amount of etching and/or sandblasting of the interior surface of the enclosure, the thickness of the coating and concentration of light-diffusing particles present. Additional parameters can be controlled and manipulated simultaneously to achieve an optimal luminous intensity distribution. For example, the embodiments herein described provide a normalized luminous intensity of 0.75 to 1.25 maintained over the range of 0 to 135 degrees of angle of measurement. In other aspects, a normalized luminous intensity of 0.75 to 1.25 maintained over the range of 0 to 135 degrees of angle of measurement. In other aspects, a normalized luminous intensity of 0.8 to 1.2 is maintained over the range of 0 to 135 degrees of angle of measurement. These performance characteristics are obtainable for Energy Star Lamps 1.4 and Energy Star Lamps 1.0, for example.

Any aspect or features of any of the embodiments described herein can be used with any feature or aspect of any other embodiments described herein or integrated together or implemented separately in single or multiple components. It should be understood that features from any of the various embodiments or described herein can be combined together to form other embodiments as would be understood by one of ordinary skill in the art with the benefit of this present description.

It cannot be overemphasized that with respect to the features described above with various example embodiments of a LED lamp, the features can be combined in various ways. For example, the various methods of including phosphor in the lamp can be combined and any of those methods can be combined with the use of various types of LED arrangements such as bare die vs. encapsulated or packaged LED devices. The embodiments shown herein are examples only, shown and described to be illustrative of various design options for a lamp with an LED array.

The various parts of an LED lamp according to example embodiments of the present disclosure can be made of any of various materials. A lamp according to embodiments of the present disclosure can be assembled using varied fastening methods and mechanisms for interconnecting the various parts. For example, in some embodiments locking tabs and holes can be used. In some embodiments, combinations of fasteners such as tabs, latches or other suitable fastening arrangements and combinations of fasteners can be used which would not require adhesives or screws. In other embodiments, adhesives, solder, brazing, screws, bolts, or other fasteners may be used to fasten together the various components.

Although specific embodiments have been illustrated and described herein, those of ordinary skill in the art appreciate that any arrangement, which is calculated to achieve the same purpose, may be substituted for the specific embodiments shown and that the present disclosure has other applications in other environments. This application is intended to cover any adaptations or variations of the present disclosure. The following claims are in no way intended to limit the scope of the present disclosure to the specific embodiments described herein.

1. An LED lamp comprising:
an enclosure about one or more LEDs, the enclosure comprising an interior surface separated from an exterior surface by a thickness, the enclosure comprising deposited on the exterior surface a light-transparent coating comprising light-diffusing particles.

2. The LED lamp of claim 1, wherein the light-diffusing particles has an average particle size distribution between 1 micron and 25 micron.

3. The LED lamp of claim 1, wherein the light-transparent coating comprises a polymer matrix having a first index of refraction and the light-diffusing particles having a second index of refraction differing from the first index of refraction by about 0.3 to about 0.01.

4. (canceled)

5. The LED lamp of claim 1, wherein the light-diffusing particles is silica, ground silica fused silica, fumed silica, precipitated silica, or chemically treated silica.

6. The LED lamp of claim 1, wherein the light-diffusing particles are present between 0.1 to 15 weight percent.

7. The LED lamp of claim 1, wherein the interior surface of the enclosure comprises a diffuse surface.

8. The LED lamp of claim 1, wherein the interior surface of the enclosure comprises a diffuse coating, the diffuse coating being the same or different as the light-transmitting coating.

9. The LED lamp of claim 1, wherein the interior surface of the enclosure is etched or sandblasted to a surface roughness capable of diffusing light emitted by the one or more LEDs.

10. The LED lamp of claim 1, wherein the thickness of the enclosure is between about 0.4 millimeters and about 1.5 millimeters.

11. The LED lamp of claim 1, wherein the light-transparent coating is of a thickness between 0.7 mm to about 1 mm.

12. The LED lamp of claim 1, wherein the thickness of the enclosure comprises one or more light filtering agents.

13. The LED lamp of claim 12, wherein the light filtering agents are one or more lanthanide elements or lanthanide compounds deposited on the interior surface or the exterior surface of the enclosure, or doped into the enclosure.

14. The LED lamp of claim 12, wherein the one or more light filtering agents are present in an amount sufficient to absorb at least a portion of the light emitted by the one or more LEDs.

15. The LED lamp of claim 1, wherein the light-transparent coating comprises a polysiloxane or polyurethane.

16. The LED lamp of claim 15, wherein the polysiloxane is a cured, elastomeric polysiloxane or the polyurethane is an elastomeric polyurethane.

17. The LED lamp of claim 1, wherein the light-transparent coating is of a thickness between 1 micron 1000 micron.

18. The LED lamp of claim 1, wherein the light-transparent coating is of a thickness between 100 micron to 500 micron.

19. The LED lamp of claim 1, wherein the light-transparent coating is of a thickness between 150 micron to 300 micron.

20. The LED lamp of claim 1, wherein the light-transparent coating is at least selectively absorbing of a portion of light having one or more wavelengths between about 350 nm to about 850 nm.

21. The LED lamp of claim 1, wherein the light-transparent coating is transparent to light between about 350 nm to about 850 nm.

22. The LED lamp of claim 1, wherein the LED lamp further comprises one or more phosphors.

23. The LED lamp of claim 1, wherein the enclosure is frangible.

24. An LED lamp comprising:
an enclosure about one or more LEDs, the enclosure comprising:
a diffuse interior surface capable of diffracting light emitted from the one or more LEDs;
an exterior surface separated from the diffuse interior surface by a thickness; and
a light-transparent coating deposited on the exterior surface, the light-transparent coating comprising light-diffusing particles.

25. An LED lamp comprising:
an enclosure about one or more LEDs, the enclosure comprising:
an interior surface;
an exterior surface separated from the interior surface by a thickness, the thickness comprising one or more lanthanide compounds and/or lanthanide elements; and
a light-transparent coating deposited on the exterior surface, the light-transparent coating comprising light-diffusing particles.

26. An LED lamp comprising:
an enclosure about one or more LEDs, the enclosure comprising:
a diffuse interior surface capable of diffracting light emitted from the one or more LEDs;
an exterior surface separated from the interior surface by a thickness, the thickness comprising one or more lanthanide compounds and/or lanthanide elements; and
a light-transparent coating deposited on the exterior surface, the light-transparent coating comprising light-diffusing particles.

27. An LED lamp comprising:
an enclosure about one or more LEDs, the enclosure comprising:
an interior diffuse surface; and
an exterior diffuse surface separated from the interior surface.

28. The LED lamp of claim 27, wherein the thickness is in the range of 0.4 millimeters to 1.7 millimeters.

29. The LED lamp of claim 27, wherein the thickness is 0.7 to 1 mm.

30. The LED lamp of claim 27, wherein the interior surface is diffuse.

31. The LED lamp of claim 27, wherein the exterior surface is coated with a light-transparent polymer matrix comprising light-diffusing particles comprising a different refractive index than the light-transparent polymer matrix.

32. The LED lamp of claim 27, wherein the enclosure is glass.

33. The LED lamp of claim 27, wherein the enclosure comprises a light filtering agent.

34. The LED lamp of claim 33, wherein the light filtering agent comprises one or more light filtering.

35. The LED lamp of claim 33 at, wherein the light filtering agent comprises neodymium.

36. A method of providing improved luminous intensity distribution of a light emitting diode (LED) lamp, the method comprising:
coating an enclosure surrounding the one or more LEDs, the enclosure having an interior surface separated from an exterior surface by a thickness, the coating comprising light-diffusing particles in an amount sufficient to diffuse light emitted by the one or more LEDs; and
providing a normalized luminous intensity of 0.75 to 1.25 maintained over the range of 0 to 135 degrees of angle of measurement.

37. The method of claim 36, wherein the coating comprises a light-transparent polymer matrix.

38. The method of claim 36, wherein the light-transparent polymer matrix is one or more polysiloxanes or polyurethanes.

39. The method of claim 36, wherein the interior surface of the enclosure comprises a diffuse coating.

40. The method of claim 36, wherein the thickness of the enclosure comprises a light filtering agent.

41. The method of claim 36, wherein the light filtering agent comprises one or more lanthanide compounds or lanthanide elements.

42. The method of claim 36, wherein the enclosure further comprises one or more lanthanide compounds or lanthanide elements deposited on the interior surface or the exterior surface of the enclosure.

43. The method of claim 36, wherein the LED lamp further comprises one or more phosphors.

44. The method of claim 36, wherein the light-diffusing particles silica, ground silica fused silica, fumed silica, precipitated silica, or chemically treated silica.

45. The method of claim 44, wherein the silicate is of an average particle size between 1 and 100 micron.

46. The method of claim 36, wherein the diffusing material is present between 0.1 to about 15 weight percent.

47. The method of claim 36, wherein the coating is of a thickness between 1 micron 1000 micron.

48. The method of claim 36, wherein the thickness is between about 0.4 millimeters and about 1.7 millimeters.

49. The method of claim 36, wherein the thickness comprises one or more lanthanide elements or lanthanide compounds.

50. The method of claim 36, wherein the one or more lanthanide elements or lanthanide compounds present in an amount sufficient to absorb at least a portion of the light emitted by the one or more LEDs, the method further comprising absorbing at least a portion of the light emitted by the one or more LEDs.

51-59. (canceled)

60. A method of providing improved luminous intensity distribution of a light emitting diode (LED) lamp, the method comprising:
diffusing light emitted by one or more LEDs capable of emitting light of one or more wavelengths by passing the one or more wavelengths of light through a coating deposited on an exterior surface of an enclosure at least partially surrounding the one or more LEDs, the coating comprising a transparent polymer matrix and an amount of light-diffusing particles; and
providing a normalized luminous intensity of between 0.75 to 1.25 maintained over a range of 0 to 135 degrees of angle of measurement.

61. The method of claim 60, further comprising absorbing at least a portion of the light emitted by the one or more LEDs before passage through the coating using one or more lanthanide elements or lanthanide compounds deposited on an interior surface of the enclosure or incorporated within the thickness of the enclosure.

62. The method of claim 60, further comprising diffusing at least a portion of the light emitted by the one or more LEDs before passage through the coating using an etched or frosted interior surface of the enclosure.

63. The method of claim 60, further comprising:
diffusing at least a portion of the light emitted by the one or more LEDs before passage through the coating using an etched or frosted interior surface of the enclosure; and
absorbing at least a portion of the light emitted by the one or more LEDs before passage through the coating using one or more lanthanide elements or lanthanide compounds deposited on an interior surface of the enclosure or incorporated within the thickness of the enclosure.

64. An enclosure for a light emitting diode (LED) lamp, the enclosure comprising:
an interior surface and an exterior surface separated by a thickness from the interior surface; and
a coating deposited on at least a portion of the enclosure, the coating comprising a light-transparent polymer matrix and an amount of light-diffusing particles distributed or dispersed therein.

65. The enclosure of claim 63, wherein the thickness comprises one or more lanthanide elements or lanthanide compounds incorporated therein.

66. The enclosure of claim 63, wherein one or more lanthanide elements or lanthanide compounds are deposited on the interior surface.

67. The enclosure of claim 63, wherein the interior surface is diffuse.

68. The enclosure of claim 63, comprising one or more lanthanide elements or lanthanide compounds incorporated therein and wherein the interior surface is diffuse.

69. The enclosure of claim 63, comprising one or more lanthanide elements or lanthanide compounds deposited on the interior surface and wherein the interior surface is diffuse.
